(19) United States
(12) Patent Application Publication
(10) Pub. No.: US 2018/0005806 A1
(43) Pub. Date: Jan. 4, 2018

(54) APPARATUS FOR PHYSICAL VAPOR DEPOSITION REACTIVE PROCESSING OF THIN FILM MATERIALS

(71) Applicant: HIA, Inc., Milpitas, CA (US)

(72) Inventors: Samuel D. Harkness, IV, Albany, CA (US); Quang N. Tran, San Jose, CA (US)

(73) Assignee: HIA, Inc., Milpitas, CA (US)

(21) Appl. No.: 15/638,242

(22) Filed: Jun. 29, 2017

Related U.S. Application Data
(60) Provisional application No. 62/356,376, filed on Jun. 29, 2016.

(51) Int. Cl. H01J 37/34; C23C 14/35

(52) U.S. Cl. CPC H01J 37/345; C23C 14/351

(57) ABSTRACT

An apparatus has a cathode target with a cathode target outer perimeter. An inner magnetic array with an inner magnetic array inner perimeter is at the cathode target outer perimeter. An outer magnetic array has an outer magnetic array outer perimeter larger than the inner magnetic array inner perimeter. The inner magnetic array and the outer magnetic array are concentric and each have a single, common, parallel magnetic orientation to form a magnetic field environment that defines a plasma confinement zone adjacent the target cathode and the plasma confinement zone causes a gas operative as a reactive gas and sputter gas to become ionized and thus be directed to the target cathode and cause a second set of ions including species from the target to disperse across a substrate.

### CROSS-REFERENCE TO RELATED APPLICATION

This application claims priority to U.S. Provisional Patent Application Ser. No. 62/356,376, filed Jun. 29, 2016, the contents of which are incorporated herein by reference.

### FIELD OF THE INVENTION

This invention relates generally to material processing. More particularly, this invention relates to an apparatus for physical vapor deposition reactive processing of thin film materials.

### BACKGROUND OF THE INVENTION

The preferred mode of producing insulating thin films has been to reactively sputter metallic targets with a mix of inert working gas and reaction species (e.g., N₂, O₂, CH₂, etc.) in a process regime known as ‘transition mode’. This refers to the intervening parameter space within which stable processing transpires without resultant target poisoning. Target poisoning occurs as the metallic target material is rendered increasingly non-conductive through action of the reactant gas species creating insulating films in the near surface causing lower sputter yield. Although effective, the process is limited in terms of film quality capability as a certain fraction of un-reacted metallic species is certain to join the adsorbate, resulting in increased film pinhole density, lower resistivity, and lower optical transparency (free carrier adsorption in the red-infrared region). Also, the deposition rate is limited and is generally lower than deposition via competing technologies, such as plasma enhanced chemical vapor deposition (PECVD). Additionally, because traditional sputter is neutral and adsorbate species are scattered to all locations within line of sight of the cathode, build-up of high stress material and ultimate delamination raises the observed particulate level during processing.

It would be advantageous to operate with only the reactant gas species used as the sputter working gas, but for the reasons described above, this leads to target poisoning and is therefore not sustainable. In fact, when the partial pressure of reactant gas rises, the target consumes the species through a combination of implantation and chemisorption phenomena, which yields a non-linear response of measured pressure to reactant gas flow. After the target is poisoned, and the reactant flow is systematically reduced, a hysteresis response in pressure is observed as the reactant partial now acts linearly with flow due to a lack of continued consumption.

The key is to sustain erosion while maintaining the conductivity and sputter yield of the cathode material. A complicating factor is the loss of anode due to accumulation of insulating film during processing. This causes an increase in plasma impedance and accelerates the poisoning process.

Another concern related to reactive sputtering is the fact that while the reactant gas is ionized, the adsorbate comprising sputter ejected species is largely neutral and therefore is less reactive, leading to a higher fraction of free metal species in the resulting film.

As mentioned above, another popular technique for the fabrication of insulating thin films is PECVD. Using this methodology, film designers may readily produce nearly stoichiometric film compositions at acceptable deposition rates, low defectivity, film stress and requiring of moderate to low substrate temperature (to facilitate chemical reaction). However, there are defined issues arising in the form of scalability and film uniformity. Moreover, the need for complicated and costly radio frequency hardware accoutrements is costly and not easily implemented in an in-line or pass-by deposition arrangement.

### SUMMARY OF THE INVENTION

An apparatus has a cathode target with a cathode target outer perimeter. An inner magnetic array with an inner magnetic array inner perimeter is at the cathode target outer perimeter. An outer magnetic array has an outer magnetic array outer perimeter larger than the inner magnetic array inner perimeter. The inner magnetic array and the outer magnetic array are concentric and each have a single, common, parallel magnetic orientation to form a magnetic field environment that defines a plasma confinement zone adjacent the target cathode and the plasma confinement zone causes a gas operative as a reactive gas and sputter gas to become ionized and thus be directed to the target cathode and cause a second set of ions including species from the target to disperse across a substrate.

### BRIEF DESCRIPTION OF THE FIGURES

The invention is more fully appreciated in connection with the following detailed description taken in conjunction with the accompanying drawings, in which:

FIG. 1 illustrates a linear cathode source (1) that can be mounted onto a vacuum system using the attached flange (11). Utilities connections are shown for water (3, 15) and power (4). A safety cover (2) is shown as well. The externally mounted magnet housing is shown (8) situated within the mounting flange (11).

FIG. 2 is a perspective schematic diagram illustrating a cathode assembly (1). The assembly (1) is shown in relation to a substrate (13) passing by the cathode. A mirror source (14) is externally mounted to the vacuum system in this embodiment.

FIG. 3 is a perspective schematic showing the assembly (1) in lengthwise cross-section.

FIG. 4 is a cross-sectional view of a cathode assembly showing relative positioning of magnet arrays (7) and (9) along with coil (10).

FIG. 5 is a block diagram of the cathode apparatus showing field propagation from the inner magnet array (7) and the outer magnet array (9). The shield (12) allows protection from line of sight (18) coating of system ground (00).

### DESCRIPTION OF THE INVENTION

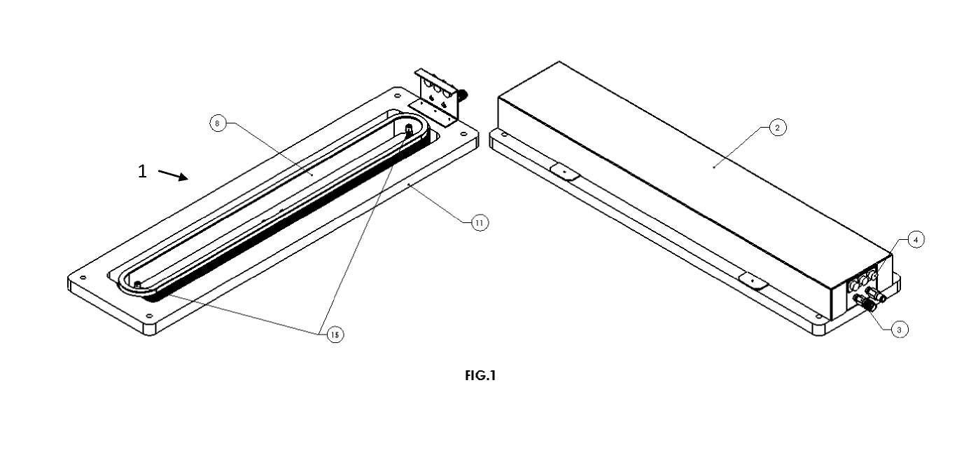

FIG. 1 is a schematic showing the basic components of the cathode processing unit (1): a source assembly connected to a vacuum mounting flange (11), and a magnetically permeable safety shield (2) that inhibits stray magnetic fields from the source assembly from interference phenomena ex situ to the tool. The safety shield is also an engineered control to inhibit users from directly accessing utility connections while powered. Utilities in the form of cooling water and power are introduced through water connections (3) and (15) and power connection (4). The magnet housing (8) for cathode magnet arrays is shown situated within the vacuum mounting plate (11).

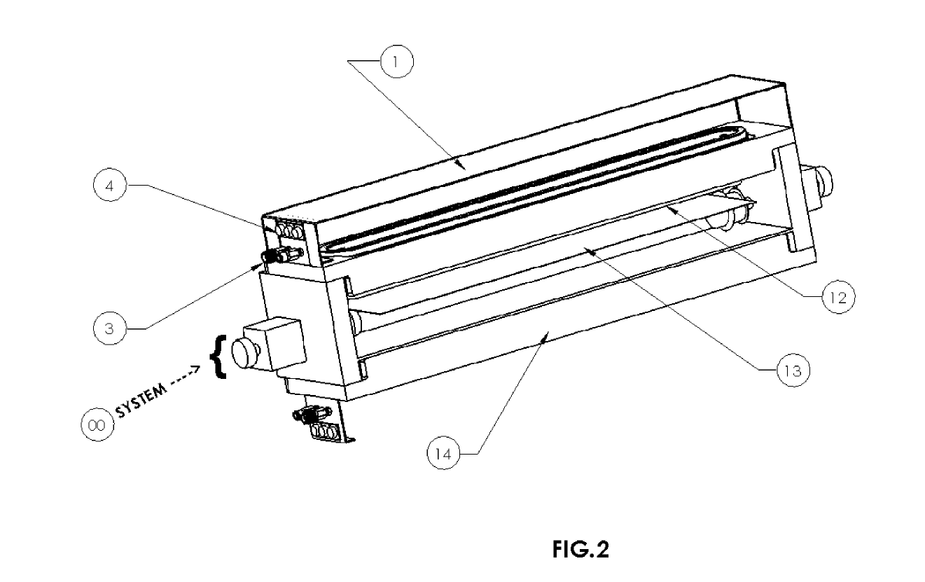

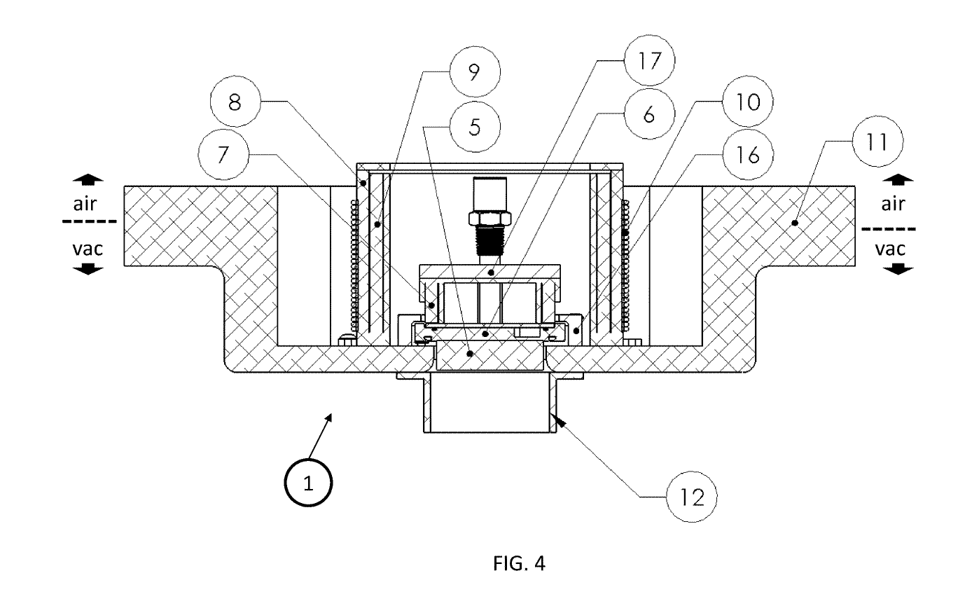

In FIG. 2, the unit is shown as connected to an ordinary vacuum system that provides general utilities of vacuum pumping, gas injection, and substrate transport through the workspace. In this embodiment, the cathode source (1) is situated above the substrate (13). A mirror source (14) is attached directly opposite the cathode assembly (1). The mirror source (14) can be ex-situ to the vacuum environment and is constructed of similar magnet arrays as the cathode assembly (1). That is, the mirror source (14) comprises at least one array (9) but may also include an inner array (7) (shown in FIG. 4). The purpose of this array is to allow rejection of fast electrons near the substrate thus protecting the substrate from excessive plasma damage. It is important that the placement of the mirror source be aligned along a common axis as the cathode assembly (1).

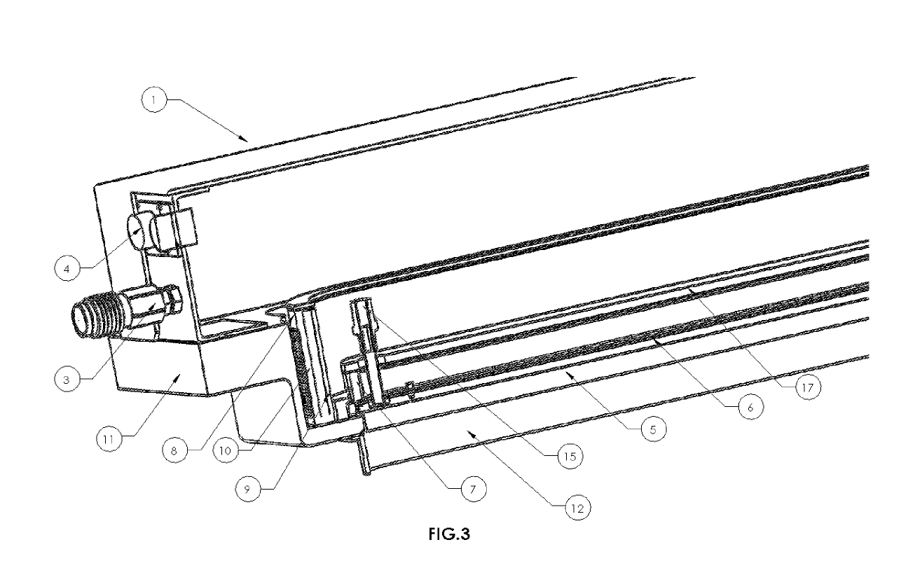

FIG. 3 is a close-up view of one end of the source assembly. The source assembly has rounded corners for both magnet arrays (7, 9), as well as for the target (5). These considerations while seemingly minor are important design aspects that inhibit re-deposition and subsequent flaking at the corner locations. This figure also shows the coil winding (10) that is placed on the atmospheric side of the magnet housing (8). When electrified with a dc power supply, this winding establishes an adjustable axial magnetic field (through the center of target (5)) between 0 and ˜200 Gauss. This field adjustment is used to optimize the ultimate position of the field zero-crossing on the surface of the target. This zero-crossing is where electron torque is maximized, where ionization cross-section is the greatest, and, hence, where the largest degree of target erosion occurs.

FIG. 4 shows the cathode assembly (1) in cross-section. The cathode assembly is comprised of a cathode target (5), and a heatsink structure (6). There is a plate (17) made of permeable material (m/m0>100) below the inner magnet array (7) that is used to hold the magnets in place. As can be seen in the figure, the inner magnet array (7) is positioned in relation to the cathode target (5) such that the innermost portion of the magnet array (7) is directly beneath the outer edge of the cathode (5). This ensures that the plasma generated in the process space will be wholly confined upon the target cathode (5). The cathode assembly is mounted on an o-ring of suitable diameter for adequate vacuum maintenance and is affixed via a clamping ring (16) to a mounting flange (11), which is ultimately connected to the vacuum transport system. An outer array of magnets is also shown (9) as peripheral to the inner array (7) and contained within the magnet housing structure (8). Around the outside of the housing (8) is shown the coil winding (10). The housing (8) is affixed to the atmospheric side of the flange (11). Finally, a shield (12) used to modulate the amount of sputter adsorbate collected on surrounding system structures is mounted to the flange (11) such that it surrounds the cathode (5).

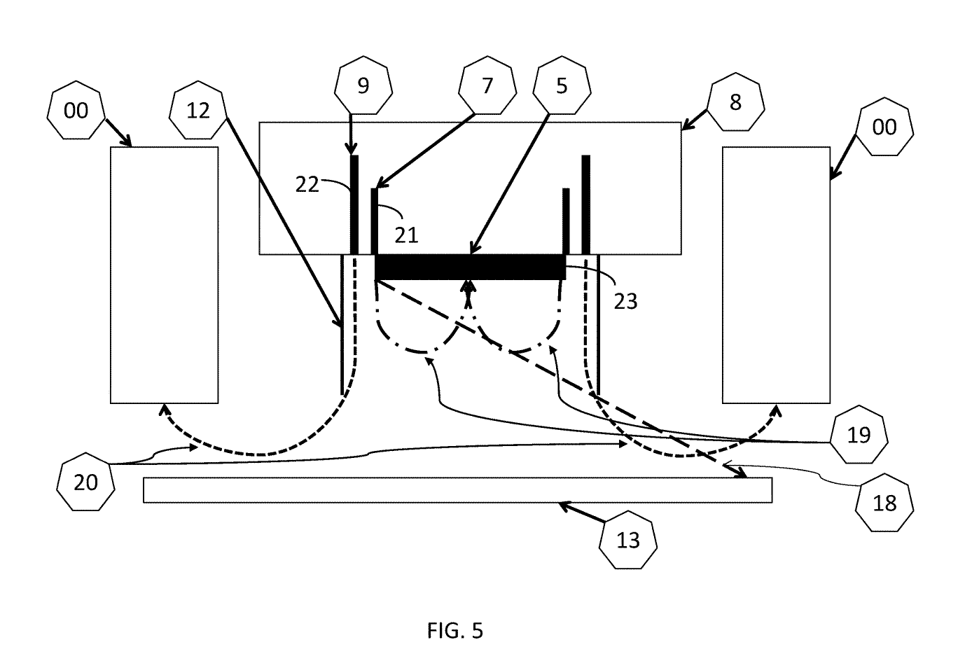

FIG. 5 is a block schematic diagram shown to illustrate the critical elements of the design as they relate to the magnetic fields generated by the magnet arrays (7, 9). Inner magnetic array (7) has an inner magnetic array inner perimeter (21). Outer magnetic array (9) has an outer magnetic array outer perimeter (22) that is larger than the inner magnetic array inner perimeter (21). The inner magnetic array (7) and outer magnetic array (9) are concentric and each have a single, common parallel magnetic orientation to form a magnetic field environment that provides plasma confinement of ionizing electrons as shown with arrows (19) which causes a gas operative as a reactive gas and sputter gas to become ionized and subsequently be directed to the target cathode (5). The fast electrons inside the plasma confinement zone simultaneously cause the ionization of sputtered species which are dispersed across a substrate (13). A second set of electrons are propagated along field lines to the space of the outer magnetic array outer perimeter (22). Some locations in this portion of the space are inhibited from being coated by the shield (12), however, electrons do bend around the line of sight curve (18) and can therefore be directed to uncoated ground plane thus ensuring stable connection to the anode.

That is, the inner magnet array (7) generates a magnetic field that confines the fast electron population that produces plasma within the dimensions of the target cathode (5). The cathode target (5) has a cathode target outer perimeter (23) at the inner magnetic array inner perimeter (21).

Due to the repulsive nature of like oriented magnets, the return field of the array (7) progresses to the outside of the array. This results in zero confinement as all charged particles (electrons) would progress along the same return field lines outside of the space above the cathode (5). The design described in this application therefore requires placement of an additional array (9) wherein the magnetic polarity is parallel to the inner array (7). In this way, the field from the array (7) is forcibly returned inward (through the inner portion of the cathode (5)) due to the same repulsive phenomena described above. With this addition, the electrons generated through collision processes are projected into the space above the cathode (5). This is illustrated in FIG. 5 with field lines (19) progressing from the magnet array (7) to the inner portion of the cathode (5) before completing the loop at the opposite end of the magnet array (7). Only that portion of the field line that is observed within the process chamber space is shown. In the case of a normally constructed magnetron, there would be a magnet of opposite polarity inside the array (7) to provide a receiving end of the flux generated. This design requires the oppositely polarized magnets to be proximal to each other in space to ensure the total capture of magnetic flux as is necessary for plasma confinement. The result of this constraint is twofold: 1) only a narrow band is created between the location of the oppositely polarized magnets where there is sufficient electron torque to generate ionization and, hence, plasma; and 2) the largest density of flux lines are found within the target (5) leaving only a small volume of plasma confinement directly above the cathode (5). Furthermore, in the case of a standard magnetron design, there is virtually no vertical progression of magnetic field lines into the process space and toward the substrate (13) enabling scant opportunity to ionize the adsorbate or accelerate ions toward the substrate. In the case of the novel design described in this application, however, the flux emanating from the inner array (7) is not drawn laterally by an oppositely polarized magnet but is driven inward by the parallel field from (9). This results in a substantially higher portion of the flux from (7) propagated in the direction perpendicular to the target (5). Moreover, the distribution of zero-crossing flux lines extends much further into the process cavity as compared to an ordinary magnetron allowing a significantly greater degree of ionization of both gas and adsorbate species.

Although the field for the outer magnet array (9) is parallel to the field from (7), it returns most prevalently to the outside of the array. This is not problematic to the operation of the new magnetron since the plasma confinement is already established within array (7). However, there are advantages to this outwardly return flux. FIG. 5 shows the flux line (20) from (9). The magnetron has a shield (12) that inhibits line-of-sight (drawn in FIG. 5 as (18) coating to a level regulated by the height of the shield piece. Structures held at ground may be preserved from film accumulation (shown as system (00) in FIG. 5). Because of the existence of field (19), electrons ex-situ to the confinement zone can be delivered to the external ground plane (00). This feature ensures consistent anode availability even as other portions of the anode become coated with potentially insulating material.

Those skilled in the art will appreciate the following design elements:

The magnet configuration supports quasi-confinement of plasma above the cathode. As shown in FIG. 4, inner magnet array (7) is arranged such that it is directly beneath the outer dimension of the cathode target above (5). The magnetic orientation of every part of this array is parallel (either all N↑, or ↓). It is also acceptable, but not necessary to arrange such that the magnet (7) surface overlaps the outer dimension of the target (5) so as to ensure that even the very outer portion of the target is within the plasma confinement zone and is thus eroded during processing. A second array (9) is shown also in FIG. 4 and is situated concentrically with respect to the inner array (7). The second array (9) is parallel in magnetic orientation to the inner array (7). The function of this array is to force the first magnetic field lines of return flux for the inner array to proceed through the inner dimension of the target. In doing so, two principal benefits are realized: 1) that the magnetic field zero-crossing (i.e., the point at which electron torque is maximized and hence wherein ionization and consequent erosion is strongest) occurs within the dimension of the cathode target (5), and 2) that the resulting plasma confinement is maintained within the dimension of the inner target array. Magnet strengths for each array are not necessarily equivalent although they are in the preferred embodiment. Strengths in both arrays can be modulated in the range of 18 MGOe to 52 MGOe with preference for approximately 45 MGOe.

A portion of the ground plane (00) is not in a line-of-sight (18) with respect to any portion of the cathode target (5) (as demonstrated pictorially in FIG. 5). This requirement allows the continual operation of the tool even after the ground plane that is within sight of the cathode target becomes insulating as a result of accumulated coating from action of the reactive sputter process. As shown in FIG. 5, the magnetic field lines (20) are away from the centroid of the unit and are toward the outer areas of the chamber. This bend allows the filtering of electrons from the plasma containing electrons and ions produced in the confinement zone since the ions possess too much mass to make the bend as efficiently as the electrons. Thus, there is a viable and sustainable path of circuit closure for the electrons to ground since that portion of ground never becomes coated with insulating material.

A mirror image magnet array (14) is set on opposite sides of the substrate/workpiece (FIG. 2). A duplicate arrangement of inner and outer magnet arrays (7, 9) is set in position such that the substrate is substantially or exactly in the middle between the two top surfaces of the arrays. However, this mirroring set is not affixed to a cathode nor is it generally within the vacuum environment. The function of the mirroring arrays is to exaggerate the flux bending near the substrate. Since the field from this unit is opposite in polarity from the cathode fields, the return lines are strongly repulsed away from progress toward the substrate (or perpendicularly with respect to the target). It is found that this element of the design is useful to both limit the flux of plasma electrons upon the substrate surface and to increase the flux of electrons on toward the stable ground plane described above. With this increased efficiency, it is possible to design the overall deposition source with more compact dimensions.

An axial electro-coil driven field adjusts ID field strength. A coil of wire (10) is wrapped around the containment structure (8) so as to produce an axial magnetic field when electrified with a given electric field direction. This is shown schematically in FIG. 4. Depending on the choice of electric field polarity, the resultant axial magnetic field may enhance or repulse the propagation of return lines from the magnet arrays described above. In general, for processing upon non-magnetic cathode materials, it is found that providing measured repulsive flux is useful in broadening the erosion groove to include a greater portion of the material near the center of the target.

### Example of Use: Silicon Nitride Films

The following is an example of the use of the apparatus in connection with the processing of silicon nitride films. A pure silicon target (5) is assembled atop heatsink structures (6) as described above. The width of the target is chosen in this description to be 100 mm so as to ensure the ease in fully eroding the entire surface of the target material. It should also be noted that while this description is provided with reference to rectangular flat targets, the source design proposed could be used in other oft-used incantations such as rotating cylindrical cathodes.

The source assembly (1) together with the mirror complement (14) are mounted to a vacuum transport device that can periodically or continually pass substrates of varying size and composition beneath (or, alternatively, above) the cathode component. The source as a whole is also designed so as to be used as a part of a plurality of similarly disposed sources also connected in situ to the same transport system. This aspect concerns considerations with respect to throughput and uptime. Each source is fit with a silicon target (5) that is bonded with solder to the heatsink (6). As the length of the target is increased to match the width of large form factor substrates, it may be advisable to assemble each target as a mosaic of smaller components.

When the base vacuum reaches acceptable levels (e.g., <1×10⁻⁵ Torr), pre-cleaning proceeds via a low pressure (1-3 mTorr), low power scrub using only argon as the working gas for a period of approximately 15 minutes. This process removes any native oxide from the surface of the silicon target and generally warms up the cathode assembly prior to general processing, which beneficially avoids thermally shocking a brittle target. During this phase, a “dummy” substrate may be placed in front of all sources to collect the ejected material and to keep it from unnecessarily coating the transport hardware surfaces beneath.

At this time, the first of the substrates (13) or panels that is scheduled for coating is inserted in the load-locking device and is brought to vacuum equivalence with the system in general. A new gas flow recipe is entered such that the specified amount of gas measured in mTorr is observed on the gauges attached to the system. In this embodiment, nitrogen delivered via gas line from a bottle pressurized with 99.999% purity N₂ is used both as the reactive gas and the sputter gas, however, it is certainly imaginable that other embodiments may include a partial pressure of other gases such as Ar, Kr, Xe, Ne, He, etc. to better effect desired film properties. The flow of the gas is regulated through control of a mass-flow controller. This flow is dispensed at regular locations near each individual source but not within a portion of the chamber that experiences plasma. Depending on the needs constricting the film or substrate, pressure can be modulated accordingly. In this description, the nitrogen is held at 2 mTorr. The target voltage is applied via a direct current power supply (generally rated to support stable, clean power up to 10 kW per unit) and plasma is generated. The coil field is then adjusted with a separate power supply until the target voltage is minimized. At this point, the sources are in stable processing mode, and coating operations can proceed.

In sum, an apparatus is configured for thin film processing in a physical vapor deposition (PVD) mode. By controlling the propagation of magnetic fields, an environment is produced between a cathode and a substrate that can be described as electron-confining near the target cathode and divergent near the substrate. This dichotomy enables high ionization cross sections near the target and thus efficient sputter and adsorbate ionization, while simultaneously providing a pathway in the form of magnetic field lines for fast electrons to escape to a ground plane not viewable in line-of-sight by the cathode surface. The combination of these effects allows not only plasma generation, but sustained operation as well throughout the erosion lifetime of the cathode material.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. An apparatus, comprising:
a cathode target with a cathode target outer perimeter;
an inner magnetic array with an inner magnetic array inner perimeter at the cathode target outer perimeter; and
an outer magnetic array with an outer magnetic array outer perimeter larger than the inner magnetic array inner perimeter, wherein the inner magnetic array and the outer magnetic array are concentric and each have a single, common, parallel magnetic orientation to form a magnetic field environment that defines a plasma confinement zone adjacent the target cathode and the plasma confinement zone causes a gas operative as a reactive gas and sputter gas to become ionized and thus directed to the target cathode and cause a second set of ions including species from the target to disperse across a substrate.

2. The apparatus of claim 1 further comprising a shield around the cathode target.

3. The apparatus of claim 2 further comprising an external ground plane surrounding the shield.

4. The apparatus of claim 3 wherein the shield defines a zone with ions and atomic species maintained within the zone by the shield and electrons escaping to the external ground plane via the magnetic field environment.

5. The apparatus of claim 1 wherein the inner magnetic array and the outer magnetic array each have a magnet strength between 18 MGOe to 52 MGOe.

6. The apparatus of claim 1 wherein the inner magnetic array and the outer magnetic array each have a magnet strength of approximately 45 MGOe.

7. The apparatus of claim 1 surrounded by a containment structure.

8. The apparatus of claim 7 further comprising a coil of wire surrounding the containment structure to produce an axial magnetic field.

9. The apparatus of claim 7 wherein the containment structure is positioned within a mounting flange for attachment to a vacuum system.

10. The apparatus of claim 9 wherein the mounting flange includes water connections and power connections.
